(19) United States
(12) Patent Application Publication
(10) Pub. No.: US 2006/0160310 A1
(43) Pub. Date: Jul. 20, 2006

(54) Semiconductor device and method for fabricating the same

(75) Inventors: Satoe Miyata, Kyoto (JP); Shuji Mizokuchi, Kyoto (JP)

Correspondence Address: MCDERMOTT WILL & EMERY LLP, 600 13TH STREET, N.W., WASHINGTON, DC, 20005-3096, US

(73) Assignee: Matsushita Electric Industrial Co., Ltd.

(21) Appl. No.: 11/261,928

(22) Filed: Oct. 31, 2005

(30) Foreign Application Priority Data
Jan. 19, 2005 (JP) 2005-011287
Aug. 25, 2005 (JP) 2005-244253

(51) Int. Cl. H01L 21/336

(52) U.S. Cl. 438/270

(57) ABSTRACT

After forming a first semiconductor region of a first conductivity type in a semiconductor substrate, a trench reaching a given portion of the first semiconductor region is formed in the semiconductor substrate. Then, after forming a gate insulating film on an inner wall of the trench, a second semiconductor region of a second conductivity type is formed on the first semiconductor region in the semiconductor substrate, and thereafter, a third semiconductor region of the first conductivity type is formed on the second semiconductor region in the semiconductor substrate. Also, a gate electrode of the first conductivity type is formed on the gate insulating film within the trench. The gate electrode is formed on the gate insulating film so as to extend over the second semiconductor region, a portion of the first semiconductor region disposed below the second semiconductor region and a portion of the third semiconductor region disposed on the second semiconductor region.

### CROSS-REFERENCE TO RELATED APPLICATIONS

This application claims priority under 35 U.S.C. §119 on Patent Application No. 2005-011287 filed in Japan on Jan. 19, 2005, the entire contents of which are hereby incorporated by reference. The entire contents of Patent Application No. 2005-244253 filed in Japan on Aug. 25, 2005 are also incorporated by reference.

### BACKGROUND OF THE INVENTION

The present invention relates to a semiconductor device having a trench MIS (Metal-Insulator-Semiconductor) gate structure and a method for fabricating the same.

A trench gate structure formed by filling a gate electrode in a trench formed in a semiconductor substrate is conventionally applied to semiconductor devices such as an IGBT (Insulated Gate Bipolar Transistor) and a MISFET (Field Effect Transistor), and is advantageous for power supply and the like in particular. For example, an IGBT having a trench gate structure has both a high input impedance characteristic of a MISFET and a low saturated voltage characteristic of a bipolar transistor, and is widely used in an uninterruptible power supply and various types of motor driving devices.

FIG. 11 is a cross-sectional view of a semiconductor device having a conventional trench MIS gate structure disclosed in Japanese Patent No. 2662217. The conventional semiconductor device of FIG. 11 has a flat surface in all masking steps while a vertical contact to a gate electrode can be formed. Specifically, on a multilayered structure of a high concentration drain region 110 and a low concentration drain region 111 of a first conductivity type (N-type), body regions 120a and 120b of a second conductivity type (P-type) spaced from each other by an upward opening trench are formed. The high concentration drain region 110 is connected to a drain contact 117. Also, source regions 121a and 121b of the first conductivity type are formed in portions of the body regions 120a and 120b in the vicinity of the upward opening trench. Metal contacts 118 and 119 for attaining contact with the source regions and the body regions are formed on the source regions 121a and 121b and the body regions 120a and 120b, respectively.

The upward opening trench extends into the low concentration drain region 111 through portions between the source regions 121a and 121b and between the body regions 120a and 120b. A gate insulating film 132 is formed on the inner wall of the upward opening trench, and a gate electrode (vertical gate) 133 is filled in the upward opening trench excluding an upper portion thereof with the gate insulating film 132 sandwiched therebetween. The upper face of the gate electrode 133 is placed at a level within the heights of the source regions 121a and 121b. Also, an insulating film 135 is filled in the upper portion of the upward opening trench on the upper face of the gate electrode 133, and the upper face of the insulating film 135 is planarized to be at the same level as the upper faces of the metal contacts 118 and 119.

Although not shown in the drawing, an insulating film is formed on the structure shown in FIG. 11, so as to give a transistor with a flat face. The semiconductor device (MISFET) having the trench MIS gate structure as described above can be easily fabricated. In addition, vertically extending channel regions 122c1 and 122c2 are formed in portions of the body regions 120a and 120b in the vicinity of the gate insulating film 132 on sides of the trench. The channel region 122c1 is sandwiched between the low concentration drain region 111 disposed below and the source region 121a disposed above. The channel region 122c2 is sandwiched between the low concentration drain region 111 disposed below and the source region 121b disposed above. Since the channel regions 122c1 and 122c2 vertically extend in this manner, carriers are allowed to continuously pass vertically in the downward direction, and therefore, the on resistance can be reduced.

### SUMMARY OF THE INVENTION

In the conventional semiconductor device, however, when integrated circuits are further refined and a distance between trenches filled with gate electrodes is smaller, an impurity included in the channel regions 122c1 and 122c2 of the body regions 120a and 120b is drawn into an oxide film in forming the oxide film in sacrificial oxidation of the inner wall of the trench or in formation of the gate oxide film. As a result, the concentration of the impurity in the channel regions is difficult to control, and hence, it is disadvantageously difficult to attain a desired threshold voltage Vt.

In consideration of the conventional disadvantage, an object of the invention is providing a semiconductor device in which the concentration of an impurity in a channel region is easily controlled so as to attain a desired threshold voltage without being affected by the impurity drawing effect in the sacrificial oxidation and the gate oxide film formation, and a method for fabricating the same.

In order to achieve the object, the method for fabricating a semiconductor device of this invention includes the steps of (a) forming a first semiconductor region of a first conductivity type in a semiconductor substrate; (b) forming a trench reaching a given portion of the first semiconductor region in the semiconductor substrate; (c) forming a gate insulating film on an inner wall of the trench; (d) forming a second semiconductor region of a second conductivity type on the first semiconductor region in the semiconductor substrate after the step (c); (e) forming a gate electrode of the first conductivity type on the gate insulating film within the trench; and (f) forming a third semiconductor region of the first conductivity type on the second semiconductor region in the semiconductor substrate, and the gate electrode is formed on the gate insulating film so as to extend over the second semiconductor region, a portion of the first semiconductor region disposed below the second semiconductor region and a portion of the third semiconductor region disposed on the second semiconductor region in the step (e).

In the method for fabricating a semiconductor device of the invention, a channel region made of the second semiconductor region of the second conductivity type is formed after forming the gate insulating film in the trench, and therefore, excessive drawing of the impurity of the second conductivity type into the insulating film derived from the formation of the gate insulating film (such as oxidation) can be prevented. Accordingly, the concentration of the impurity in the channel region can be easily controlled, and hence, a desired threshold voltage Vt can be attained.

In the method for fabricating a semiconductor device of the invention, the gate electrode is preferably formed to have an upper face thereof positioned between an upper face and a lower face of the third semiconductor region in the step (e).

Thus, since source contact can be attained on a side face of a source region positioned in an upper portion of the trench, the resistance of the source contact can be reduced.

The method for fabricating a semiconductor device of the invention preferably further includes, after the step (e), a step (g) of forming an insulating film for covering an upper face of the gate electrode within the trench, and the insulating film is preferably formed to have an upper face thereof positioned between an upper face and a lower face of the third semiconductor region.

Thus, since a source electrode can be formed on the gate electrode with the insulating film sandwiched therebetween, source regions formed on the both sides of the trench can be easily connected to each other through the source electrode.

The method for fabricating a semiconductor device of the invention preferably further includes, after the step (e), a step (h) of forming a silicide layer on a portion of the third semiconductor region exposed within the trench.

Thus, the resistance of the source contact can be further reduced.

In the method for fabricating a semiconductor device of the invention, the second semiconductor region is preferably formed by implanting an impurity of the second conductivity type into the semiconductor substrate through a plurality of ion implantations different in implantation energy.

Thus, the degree of freedom in control of the threshold voltage Vt and the degree of freedom in control of a channel length can be improved. Also, the resistance of the second semiconductor region can be suppressed, so as to prevent a trouble caused by a parasitic transistor, such as degradation of a current-voltage characteristic designated as snap back caused when a parasitic bipolar transistor is conductive.

The method for fabricating a semiconductor device of the invention preferably further includes, between the step (b) and the step (c), a step of forming an oxide film by sacrificially oxidizing the inner wall of the trench and removing the oxide film.

Thus, the inner wall of the trench can be made flat. Also, since the channel region made of the second semiconductor region is formed after the sacrificial oxidation of the inner wall of the trench, the excessive drawing of the impurity included in the second semiconductor region into the oxide film derived from the sacrificial oxidation can be prevented. Accordingly, the concentration of the impurity in the channel region can be more easily controlled, and hence, the desired threshold voltage Vt can be more definitely attained.

In the method for fabricating a semiconductor device of the invention, the step (d) is preferably executed after the step (e).

Thus, since the second semiconductor region is formed with the gate insulating film formed within the trench covered with the gate electrode, the second semiconductor region can be formed without damaging the gate insulating film.

In the method for fabricating a semiconductor device of the invention, the step (e) preferably includes a sub-step (e1) of filling a conducting film in the trench and a sub-step (e2) of forming the gate electrode by etching the conducting film, the step (d) is preferably executed between the sub-step (e1) and the sub-step (e2), and the second semiconductor region is preferably formed by introducing an impurity of the second conductivity type into the semiconductor substrate through the conducting film by ion implantation.

Thus, the semiconductor device having a trench MIS gate structure can be fabricated while preventing degradation of the film quality of the gate insulating film derived from the ion implantation.

The semiconductor device of this invention includes a first semiconductor region of a first conductivity type formed in a semiconductor substrate; a second semiconductor region of a second conductivity type formed on the first semiconductor region in the semiconductor substrate; a third semiconductor region of the first conductivity type formed on the second semiconductor region in the semiconductor substrate; a trench penetrating the third semiconductor region and the second semiconductor region and reaching the first semiconductor region; a gate insulating film formed on an inner wall of the trench; and a gate electrode of the first conductivity type formed on the gate insulating film within the trench, and the gate electrode is formed on the gate insulating film so as to extend over the second semiconductor region, a portion of the first semiconductor region disposed below the second semiconductor region and a portion of the third semiconductor region disposed on the second semiconductor region and includes an impurity of the second conductivity type. In this case, in a concentration distribution of the impurity of the second conductivity type in a portion of the second semiconductor region disposed between the first semiconductor region and the third semiconductor region on a side of the trench, concentrations in positions away respectively upward and downward from a peak position by 0.25 μm are preferably lower than a half of a peak concentration.

Since the semiconductor device of the invention is fabricated by the method of fabricating a semiconductor device of the invention, an impurity profile in the second semiconductor region is abrupt, namely, the impurity profile can be prevented from being broad, and therefore, cancellation of an impurity concentration in source/drain regions can be suppressed. Specifically, the resistance of the device can be advantageously reduced. Also, since the threshold voltage can be easily controlled by controlling a peak concentration of the impurity profile, the channel length can be advantageously shortened.

In the semiconductor device of the invention, the gate electrode preferably has an upper face positioned between an upper face and a lower face of the third semiconductor region.

Thus, since source contact can be attained on a side face of a source region disposed in an upper portion of the trench, the resistance of the source contact can be reduced.

The semiconductor device of the invention preferably further includes an insulating film covering an upper face of the gate electrode within the trench, the insulating film preferably has an upper face positioned between an upper face and a lower face of the third semiconductor region.

Thus, a source electrode can be formed on the gate electrode with the insulating film sandwiched therebetween, and hence, source regions formed on the both sides of the trench can be easily connected to each other through the source electrode. Also, in this case, a silicide layer is preferably formed on a portion of the third semiconductor region disposed above the insulating film within the trench. Thus, the resistance of the source contact can be further reduced.

In the semiconductor device of the invention, a concentration distribution of the impurity of the second conductivity type in the second semiconductor region preferably has two peaks.

Thus, the degree of freedom in the control of the threshold voltage Vt and the degree of freedom in the control of the channel length can be improved.

In the semiconductor device of the invention, a concentration distribution of the impurity of the second conductivity type in the second semiconductor region preferably has three or more peaks.

Thus, the degree of freedom in the control of the threshold voltage Vt and the degree of freedom in the control of the channel length can be improved. Also, the resistance of the second semiconductor region can be suppressed, so as to prevent a trouble caused by a parasitic transistor, such as degradation of a current-voltage characteristic designated as snap back caused when a parasitic bipolar transistor is conductive.

In the semiconductor device of the invention, the first semiconductor region preferably includes a fourth semiconductor region including an impurity of the first conductivity type in a relatively high concentration and a fifth semiconductor region provided on the fourth semiconductor region and including the impurity of the first conductivity type in a relatively low concentration.

Thus, the portion of the second semiconductor region working as the channel region is in contact with the fifth semiconductor region including the first conductivity type impurity in a relatively low while it is away from the fourth semiconductor region including the first conductivity type impurity in a relatively high concentration. Therefore, an on current can be reduced.

In the semiconductor device of the invention, the impurity of the second conductivity type included in the gate electrode may be introduced into the gate electrode through ion implantation performed for forming the second semiconductor region.

As described so far, according to the present invention, since the lowering of the impurity concentration in the channel region derived from the oxide film formation such as the sacrificial oxidation and the gate oxide film formation can be suppressed, the impurity concentration in the channel region can be easily controlled, and therefore, a desired threshold voltage Vt can be attained. Furthermore, since the impurity concentration distribution in the channel region can be made abrupt, a shorter channel length can be realized in accordance with refinement of the device.

Moreover, the present invention is applicable to any of semiconductor devices having a trench MIS gate structure with a high breakdown voltage and used for power supply in particular, such as a MISFET and an IGBT.

### BRIEF DESCRIPTION OF THE DRAWINGS

FIG. 1A is a perspective view of a semiconductor device having a trench gate structure according to Embodiment 1 of the invention and FIG. 1B is a diagram of a concentration profile of an impurity of a second conductivity type along the vertical direction of the semiconductor device of FIG. 1A.

FIG. 2A is a diagram of a relationship, found by the present inventors, of a rate to a peak concentration of an impurity concentration in positions away from a peak position respectively upward and downward by 0.25 μm (“rate of conc. at peak±0.25 μm”) with an on resistance (“Ron”) and an effective channel length (“Leff”) obtained when the peak concentration is fixed, and FIG. 2B is a diagram of a relationship, found by the present inventors, between the rate to the peak concentration of the impurity concentration in the positions away from the peak position respectively upward and downward by 0.25 μm (“rate of conc. at peak±0.25 μm”) and the on resistance (“Ron”) obtained when the peak concentration is fixed.

FIGS. 3A, 3B, 3C, 3D, 3E and 3F are cross-sectional views for showing procedures in a method for fabricating the semiconductor device of Embodiment 1 of the invention, and specifically, FIGS. 3A, 3C and 3E are cross-sectional views thereof taken from the front side of FIG. 1A and FIGS. 3B, 3D and 3F are cross-sectional views thereof taken from the right side of FIG. 1A.

FIGS. 4A, 4B, 4C, 4D, 4E and 4F are cross-sectional views for showing other procedures in a method for fabricating the semiconductor device of Embodiment 1 of the invention, and specifically, FIGS. 4A, 4C and 4E are cross-sectional views thereof taken from the front side of FIG. 1A and FIGS. 4B, 4D and 4F are cross-sectional views thereof taken from the right side of FIG. 1A.

FIGS. 5A, 5B, 5C, 5D, 5E and 5F are cross-sectional views for showing other procedures in a method for fabricating the semiconductor device of Embodiment 1 of the invention, and specifically, FIGS. 5A, 5C and 5E are cross-sectional views thereof taken from the front side of FIG. 1A and FIGS. 5B, 5D and 5F are cross-sectional views thereof taken from the right side of FIG. 1A.

FIGS. 6A, 6B, 6C, and 6D are cross-sectional views for showing other procedures in a method for fabricating the semiconductor device of Embodiment 1 of the invention, and specifically, FIGS. 6A and 6C are cross-sectional views thereof taken from the front side of FIG. 1A and FIGS. 6B and 6D are cross-sectional views thereof taken from the right side of FIG. 1A.

FIG. 7 is a diagram of a concentration profile of an impurity of a second conductivity type along a vertical direction of a semiconductor device having a trench gate structure according to Embodiment 2 of the invention.

FIG. 8 is a diagram of a concentration profile of an impurity of a second conductivity type along a vertical direction of a semiconductor device having a trench gate structure according to Embodiment 3 of the invention.

FIGS. 9A and 9B are diagrams of a variation of the semiconductor devices according to Embodiments 1 through 3 of the invention, and specifically, FIG. 9A shows a modified cross-sectional structure taken from the front side of FIG. 1A and FIG. 9B shows a modified cross-sectional structure taken from the right side of FIG. 1A.

FIGS. 10A and 10B are diagrams of a variation of the semiconductor devices according to Embodiments 1 through 3 of the invention, and specifically, FIG. 10A shows a modified cross-sectional structure taken from the front side of FIG. 1A and FIG. 10B shows a modified cross-sectional structure taken from the right side of FIG. 1A.

FIG. 11 is a cross-sectional view of a semiconductor device having a conventional trench MIS gate structure.

### DETAILED DESCRIPTION OF THE INVENTION

Now, preferred embodiments of the semiconductor device and the fabrication method for the same according to the present invention will be described with reference to the accompanying drawings. Although a MISFET having a vertical trench gate structure is exemplified in each embodiment described below, this invention is applicable to any of general semiconductor devices having trench MIS gate structures such as a vertical trench IGBT, a vertical MISFET and a horizontal trench MISFET. Also, although a first conductivity type and a second conductivity type are described respectively as an N-type and a P-type in the following description, the first conductivity type and the second conductivity type may be respectively a P-type and an N-type.

### Embodiment 1

—Structure of Semiconductor Device—

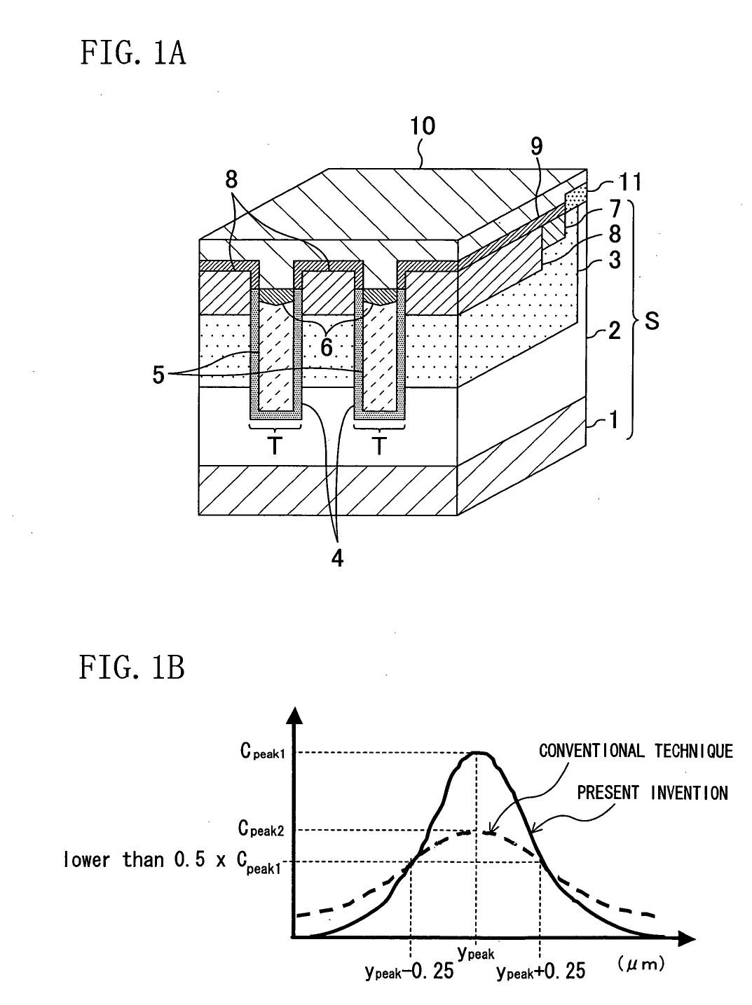

FIG. 1A is a perspective view of a semiconductor device having a trench gate structure according to Embodiment 1 of the invention, and FIG. 1B is a diagram of a concentration profile of an impurity of a second conductivity type along the vertical direction of the semiconductor device of FIG. 1A. In FIG. 1A, a barrier metal layer provided below a contact electrode 10 is omitted so that the structure can be clearly understood.

As shown in FIG. 1A, the semiconductor device of this embodiment includes a high concentration N-type drain region 1 formed at least in a region in the vicinity of the back surface of a semiconductor substrate S of silicon, a low concentration N-type drain region 2 formed on the high concentration N-type drain region 1 in the semiconductor substrate S, a P-type substrate region 3 selectively provided on the low concentration N-type drain region 2 in the semiconductor substrate S, a high concentration N-type source region 8 selectively provided on the P-type substrate region 3 in the semiconductor substrate S, and a high concentration P-type substrate region 7 selectively provided on the P-type substrate region 3 to be adjacent to the high concentration N-type source region 8 in the semiconductor substrate S. In this case, the semiconductor substrate S is composed of, for example, a silicon substrate in which the high concentration N-type drain region 1 is formed and a silicon epitaxial layer formed on the silicon substrate, and the silicon epitaxial layer corresponds to the low concentration N-type drain region 2 in this embodiment.

The concentration of a P-type impurity in the high concentration P-type substrate region 7 is higher than that in the P-type substrate region 3. Also, the high concentration N-type source region 8 and the high concentration P-type substrate region 7 are formed so as to extend to the top face of the semiconductor substrate S. Furthermore, the P-type substrate region 3 extends to the top face of the semiconductor substrate S on a side of the high concentration P-type substrate region 7 not in contact with the high concentration N-type source region 8, and the low concentration N-type drain region 2 extends to the top face of the semiconductor substrate S on a side of the P-type substrate region 3.

Furthermore, a plurality of trenches T that penetrate through the high concentration N-type source region 8 and the P-type substrate region 3 and reach the low concentration N-type drain region 2 are formed in the semiconductor substrate S in parallel to one another. A gate insulating film 4 is formed on the inner wall of each trench T excluding an upper portion thereof, and an N-type gate electrode 5 is filled in the trench T excluding the upper portion thereof with the gate insulating film 4 sandwiched therebetween. Also, a buried insulating film 6 is formed on the gate electrode 5 within each trench T. At this point, the upper face of the gate electrode 5 is placed at a level within the height of the high concentration N-type source region 8 (namely, between the upper face and the lower face of the high concentration N-type source region 8). Furthermore, the upper face of the buried insulating film 6 is also placed at a level within the height of the high concentration N-type source region 8 (namely, between the upper face and the lower face of the high concentration N-type source region 8). Accordingly, the thickness of the buried insulating film 6 is smaller than the height of the high concentration N-type source region 8. Also, the N-type gate electrode 5 includes a P-type impurity introduced by ion implantation performed also for the P-type substrate region 3 (namely, ion implantation performed for forming the P-type substrate region 3).

Furthermore, a silicide layer 9 is formed on the high concentration N-type source region 8 and the high concentration P-type substrate region 7 to be in contact with their upper faces. The silicide layer 9 is formed to be in contact with the upper end of the gate insulating film 4 along the upper wall of each trench T.

Moreover, a protection insulating film 11 of an oxide film is formed on portions of the P-type substrate region 3 and the low concentration N-type drain region 2 extending to the top face of the semiconductor substrate S.

A contact electrode 10 of an Al layer is formed on the silicide layer 9, the protection insulating film 11 and the buried insulating film 6 within the trench T. The contact electrode 10 is electrically connected to the high concentration N-type source region 8 and the high concentration P-type substrate region 7 through the silicide layer 9.

Although not shown in FIG. 1A, a barrier metal layer may be formed below the contact electrode 10 and on the silicide layer 9, the protection insulating film 11 and the buried insulating film 6.

FIG. 1B shows a concentration profile of the impurity of the second conductivity type (the P-type), which determines a threshold voltage Vt, along the depth direction in a portion of the P-type substrate region 3 sandwiched between the adjacent trenches T (corresponding to a channel region). For comparison, a concentration profile of a second conductivity type impurity along the depth direction in a conventional substrate region of the second conductivity type (corresponding to a channel region) is also shown in FIG. 1B.

As shown in FIG. 1B, as a characteristic of the semiconductor device of this embodiment, in the concentration profile of the second conductivity type impurity in the P-type substrate region 3 for determining the threshold voltage Vt, concentrations of the second conductivity type impurity in positions yₚₑₐₖ+0.25 and yₚₑₐₖ−0.25 away from a peak position yₚₑₐₖ respectively upward and downward by 0.25 μm are lower than a half of a peak concentration Cₚₑₐₖ₁.

On the contrary, in the conventional profile, concentrations of the second conductivity type impurity in the positions yₚₑₐₖ+0.25 and yₚₑₐₖ−0.25 away from the peak position yₚₑₐₖ respectively upward and downward by 0.25 μm are not lower than a half of the peak concentration Cₚₑₐₖ₁.

Accordingly, in the semiconductor device of this embodiment, a desired threshold voltage Vt can be attained with a small dose, and hence, the impurity concentration in the channel region in the P-type substrate region 3 can be easily controlled. Furthermore, since the impurity concentration distribution in the channel region is abrupt, a shorter channel can be realized in accordance with the refinement of the device.

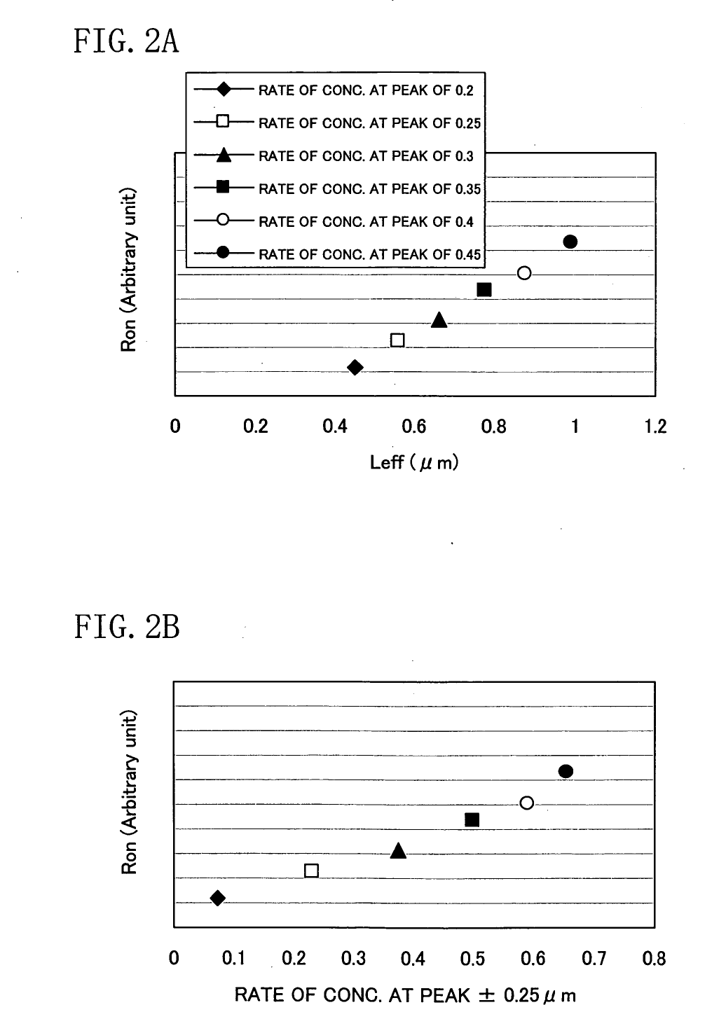

FIG. 2A is a diagram of a relationship, found by the present inventors, of a rate to the peak concentration of the impurity concentration in the positions away from the peak position respectively upward and downward by 0.25 μm (“rate of conc. at peak±0.25 μm”) with an on resistance (“Ron”) and an effective channel length (“Leff”) obtained when the peak concentration is fixed.

FIG. 2B is a diagram of a relationship, found by the present inventors, between the rate to the peak concentration of the impurity concentration in the positions away from the peak position respectively upward and downward by 0.25 μm (“rate of conc. at peak±0.25 μm”) and the on resistance (“Ron”) obtained when the peak concentration is fixed.

As shown in FIGS. 2A and 2B, a sufficiently low on resistance Ron and a sufficiently short effective channel length Leff can be attained at the rate of concentration at peak lower than 0.5. Also, as the rate of concentration at peak is lower, namely, as the concentration profile is more abrupt, the on resistance Ron is lower and the effective channel length Leff is shorter.

—Fabrication Procedures—

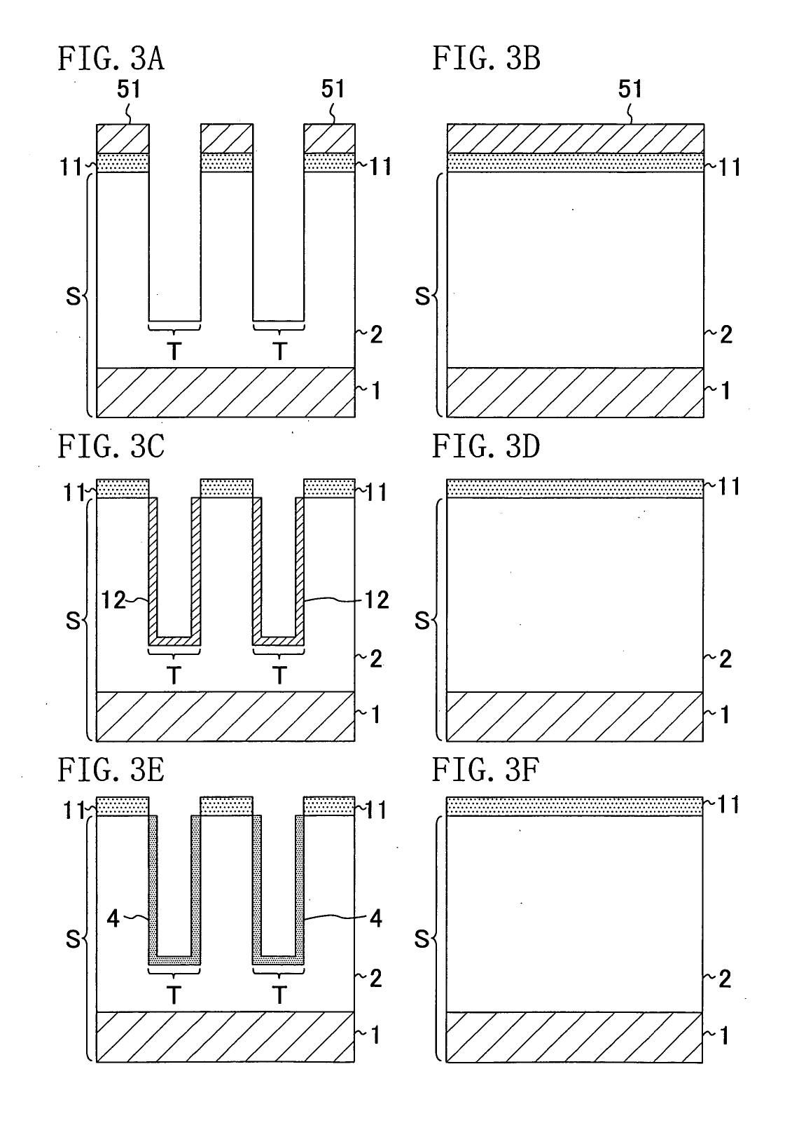

FIGS. 3A through 3F, 4A through 4F, 5A through 5F and 6A through 6D are cross-sectional views for showing procedures in a method for fabricating the semiconductor device of Embodiment 1 of the invention. In particular, FIGS. 3A, 3C, 3E, 4A, 4C, 4E, 5A, 5C, 5E, 6A and 6C show cross-sectional structures taken from the front side of FIG. 1A, and FIGS. 3B, 3D, 3F, 4B, 4D, 4F, 5B, 5D, 5F, 6B and 6D show cross-sectional structures taken from the right side of FIG. 1A.

First, as shown in FIGS. 3A and 3B, a high concentration N-type drain region 1 (having a thickness of, for example, 500 μm) including an N-type impurity in a concentration of, for example, approximately 3×10¹⁹ atoms/cm³ and a low concentration N-type drain region 2 (having a thickness of, for example, 3 through 5 μm) including the N-type impurity in a concentration of, for example, approximately 3×10¹⁶ atoms/cm³ are successively formed in a semiconductor substrate S of silicon from its back surface side. The semiconductor substrate S may be obtained by, for example, forming the low concentration N-type drain region 2 of a silicon epitaxial layer through epitaxial growth on a silicon substrate in which the high concentration N-type drain region 1 has been formed. Thereafter, after forming a protection insulating film 11 of, for example, an oxide film with a-thickness of approximately 250 nm on the semiconductor substrate S, a photoresist mask 51 having an opening in a trench gate forming region is formed on the protection insulating film 11. Then, the protection insulating film 11 and a part of the low concentration N-type drain region 2 of the semiconductor substrate S are selectively etched by dry etching using the photoresist mask 51, thereby forming a trench T (having a width of, for example, approximately 250 nm) reaching a portion of the low concentration N-type drain region 2 at a depth of, for example, approximately 1.3 μm. At this point, the trench may be formed as follows: After etching the protection insulating film 11 by using the photoresist mask 51, the photoresist mask 51 is removed, and thereafter, a part of the low concentration N-type drain region 2 of the semiconductor substrate S is selectively etched by using the protection insulating film 11 where an opening has been formed.

It is noted that the protection insulating film 11 shown in FIG. 3B is used as an implantation protecting film in ion implantation described below and may be removed after the ion implantation or allowed to remain for reducing the number of procedures.

Next, as shown in FIGS. 3C and 3D, a sacrificial oxide film 12 is formed on the inner wall of the trench T. Thereafter, the sacrificial oxide film 12 is removed by wet etching. Thus, the inner wall of the trench T can be made flat.

Then, as shown in FIGS. 3E and 3F, a gate insulating film 4 of, for example, silicon oxide with a thickness of, for example, 30 nm is formed on the inner wall of the trench T by thermal oxidation.

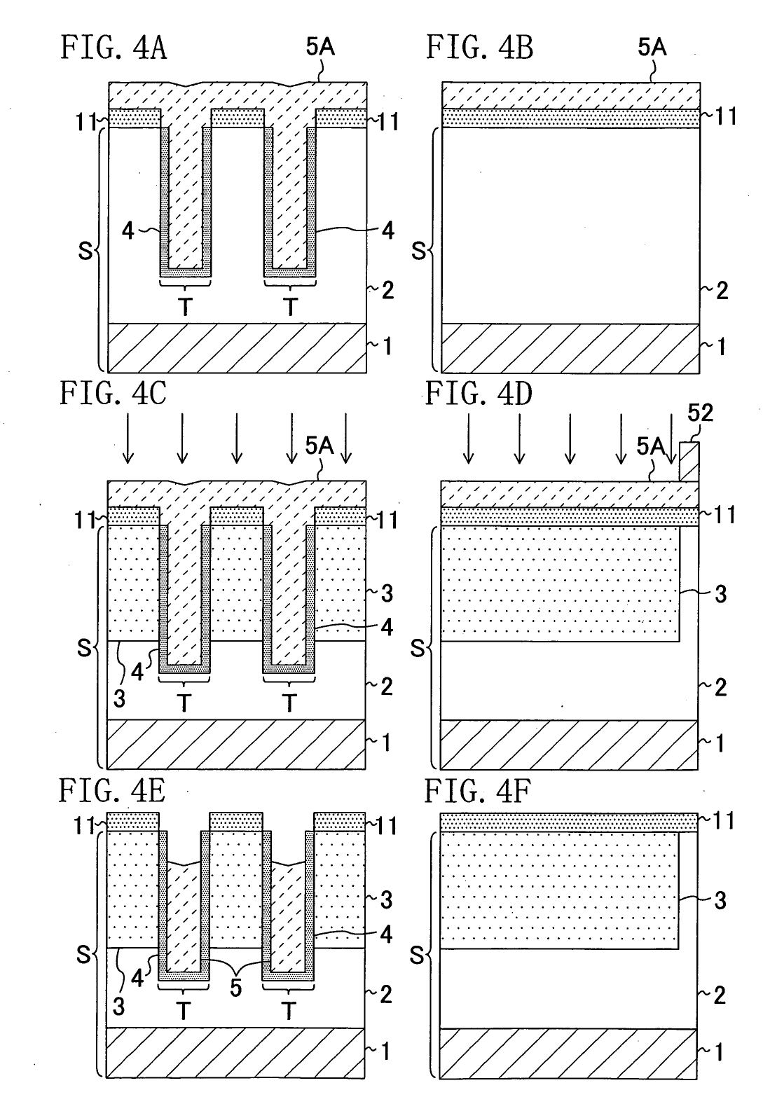

Next, as shown in FIGS. 4A and 4B, a polysilicon film 5A with a thickness of, for example, approximately 400 nm to be made into a gate electrode 5 is deposited on the semiconductor substrate S so as to be filled in the trench T. Thereafter, an N-type impurity is ion implanted into the polysilicon film 5A, and the resultant polysilicon film 5A is subjected to activation annealing (performed at a temperature of, for example, approximately 950° C.) for activating the implanted impurity.

Then, as shown in FIGS. 4C and 4D, a photoresist mask 52 having an opening in a predetermined region including a source region and a high concentration P-type substrate region to be formed later is formed on the polysilicon film 5A. Thereafter, boron, that is, a P-type impurity, is introduced through the polysilicon film 5A and the protection insulating film 11 into an upper portion of the low concentration N-type drain region 2 by the ion implantation using the photoresist mask 52, thereby forming a P-type substrate region 3 having a junction depth of, for example, approximately 1 μm, which is smaller than the depth of the trench T. In this case, the ion implantation is performed at implantation energy of, for example, 400 through 600 keV and a dose of, for example, 6.0×10¹² ions/cm². At this point, the P-type impurity of boron is introduced also into the polysilicon film 5A to be made into the gate electrode 5.

Next, after removing the photoresist mask 52, the polysilicon film SA is etched back as shown in FIGS. 4E and 4F, so as to remove a portion of the polysilicon film 5A disposed on the protection insulating film 11 and to remove a portion of the polysilicon film 5A disposed in an upper portion of the trench T to a given depth. In this manner, the polysilicon film 5A is filled in the trench T excluding the upper portion thereof, and thus, the gate electrode 5 is formed. At this point, a level difference between the top face of the semiconductor substrate S and the upper face of the gate electrode 5 is preferably approximately 200 through 500 nm. Thus, the side face of a source region positioned in the upper portion of the trench T can be exposed, and hence, a source electrode can be formed on the side face of the source region, so as to reduce the resistance of source contact.

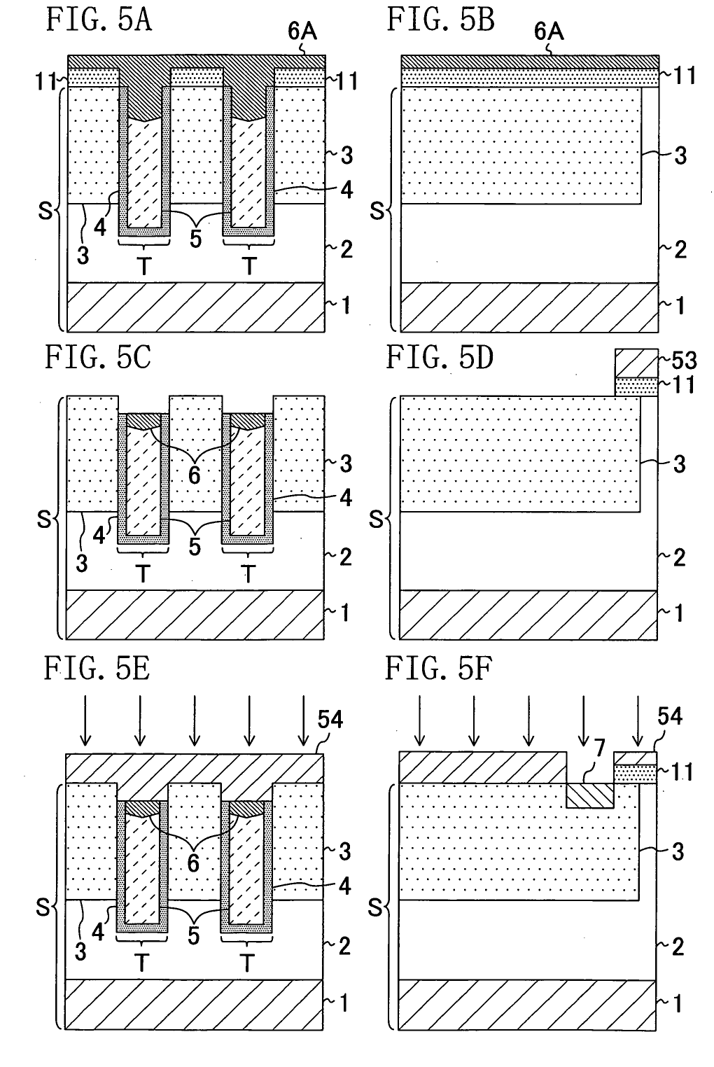

Next, as shown in FIGS. 5A and 5B, after depositing a BPSG (boro-phospho silicate glass) film 6A to be made into a buried insulating film 6 on the semiconductor substrate S so as to fill the trench T, annealing (at a temperature of approximately 850° C.) is performed for making the BPSG film 6A reflow.

Then, as shown in FIGS. 5C and 5D, the BPSG film 6A is etched back so as to expose the upper face of the protection insulating film 11. At this point, the upper face of the BPSG film 6A remaining within the trench T is planarized to be at substantially the same level as the upper face of the protection insulating film 11. Thereafter, a photoresist mask 53 having an opening in a trench gate structure MIS transistor forming region is formed on the protection insulating film 11. At this point, the photoresist mask 53 is formed so as to overlap an end portion of the P-type substrate region 3. Then, the protection insulating film 11 and the BPSG film 6A remaining within the trench T are etched back by using the photoresist mask 53, so as to expose the top face of the semiconductor substrate S (namely, the P-type substrate region 3). Furthermore, an upper portion of the BPSG film 6A remaining within the trench T is removed, so that the upper face of the resultant BPSG film 6A can be positioned at a given depth from the top face of the semiconductor substrate S. In this manner, the buried insulating film 6 covering the upper face of the gate electrode 5 within the trench T is formed. At this point, a level difference from the top face of the semiconductor substrate S to the upper face of the buried insulating film 6 is preferably approximately 50 through 350 nm.

Although the photoresist mask 53 is formed after etching back the BPSG film 6A formed on the protection insulating film 11 in this embodiment, the photoresist mask 53 may be formed on the BPSG film 6A before etching back the BPSG film 6A and the BPSG film 6A and the protection insulating film 11 may be etched back thereafter.

Next, after removing the photoresist mask 53, a photoresist mask 54 having an opening in a predetermined region for forming a high concentration P-type substrate region is formed on the semiconductor substrate S (namely, the P-type substrate region 3) as shown in FIGS. 5E and 5F. Then, a P-type impurity is selectively introduced into a part of a surface portion of the P-type substrate region 3 by the ion implantation using the photoresist mask 54, thereby forming a high concentration P-type substrate region 7. Specifically, a peak concentration of the P-type impurity in the high concentration P-type substrate region 7 is higher than that in the P-type substrate region 3.

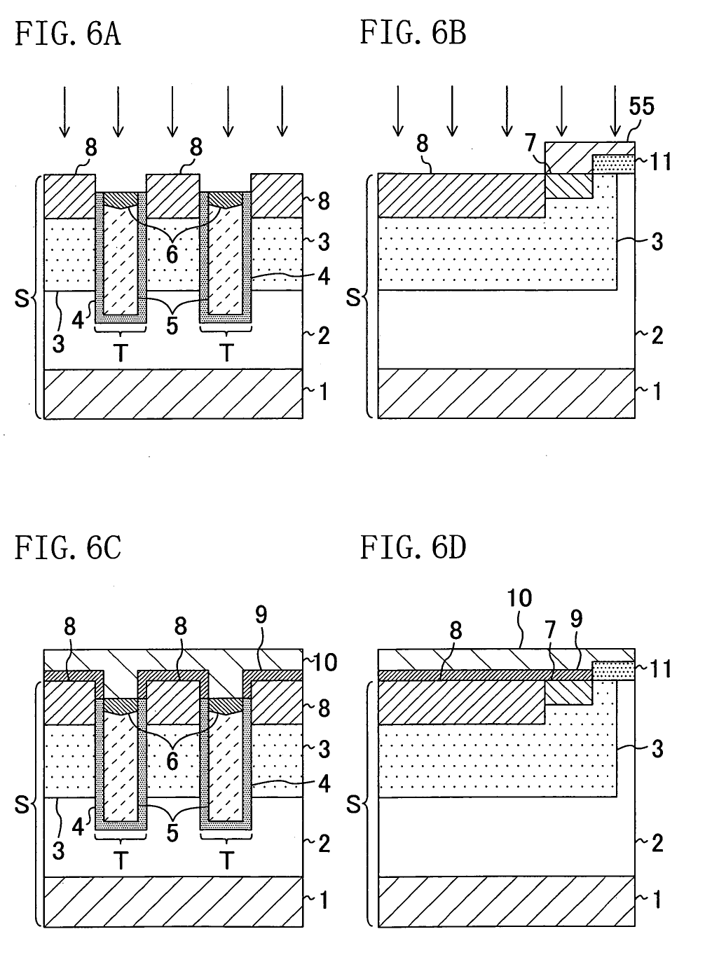

Next, as shown in FIGS. 6A and 6B, a photoresist mask 55 having an opening in a region for forming a source region and covering the high concentration P-type substrate region 7 and the protection insulating film 11 is formed on the semiconductor substrate S (namely, the P-type substrate region 3). Thereafter, an N-type impurity (such as arsenic and phosphorus) is selectively introduced into a part of a surface portion of the P-type substrate region 3 by the ion implantation using the photoresist mask 55, thereby forming a high concentration N-type source region 8. At this point, the high concentration N-type source region 8 is formed so as to have a junction depth deeper than the lower face of the buried insulating film 6 (namely, the upper face of the gate electrode 5). In this case, the ion implantation of arsenic is performed at implantation energy of, for example, 140 keV and a dose of, for example, 4.0×10¹⁵ ions/cm². Also, the ion implantation of phosphorus is performed at implantation energy of, for example, 190 keV and a dose of, for example, 4.0×10¹⁵ ions/cm². For securing overlap between the gate and the source, the upper face of the gate electrode 5 is preferably placed within the height of the high concentration N-type source region 8. In other words, it is necessary in this embodiment to make deep the high concentration N-type source region 8 in order to form the gate electrode 5 in the trench T excluding the upper portion thereof.

Next, after removing the photoresist mask 55, a silicide layer 9 is selectively formed on the exposed face of the semiconductor substrate S, namely, on the high concentration N-type source region 8 and the high concentration P-type substrate region 7 as shown in FIGS. 6C and 6D, and then, a contact electrode 10 of, for example, an Al layer is formed so as to cover the gate electrode 5 (the buried insulating film 6) and the silicide layer 9. The contact electrode 10 is electrically connected to the high concentration N-type source region 8 and the high concentration P-type substrate region 7 through the silicide layer 9. Although not shown in FIGS. 6C and 6D, a barrier metal layer may be formed over the semiconductor substrate S before forming the Al layer used as the contact electrode 10.

Thereafter, although not shown in the drawings, an interlayer insulating film, a contact plug, an interconnect to be connected to the contact plug and the like are formed on the semiconductor substrate S by known technique.

In the present embodiment described so far, the following effects can be attained:

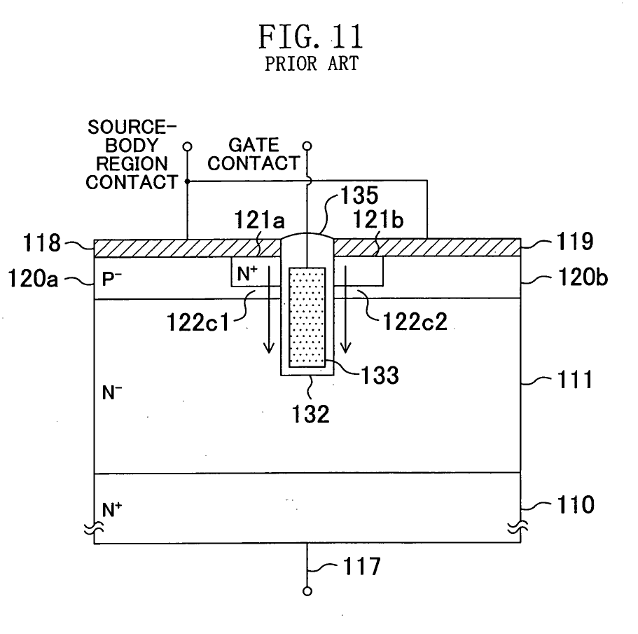

In the formation of a gate oxide film or the formation of a sacrificial oxide film, an impurity included in a silicon-oxide film interface (in the side of silicon) is drawn into the oxide film through annealing and oxidation of the silicon. Therefore, in the conventional technique shown in FIG. 11, it is difficult to control the impurity concentration in the channel region, and hence, it is necessary to provide a measure for reducing process variation or to form a body region at a high dose in order to attain a desired threshold voltage.

On the contrary, in the case where the ion implantation for forming the substrate region working as the channel region is performed after the formation of the gate oxide film or the sacrificial oxide film as in this embodiment, a threshold voltage can be controlled without being affected by the aforementioned drawing effect.

Specifically, in this embodiment, the channel region of the P-type substrate region 3 is formed as shown in FIGS. 4C and 4D after the sacrificial oxide film formation of FIGS. 3C and 3D and the gate oxide film formation of FIGS. 3E and 3F. Therefore, the P-type impurity can be prevented from being excessively drawn into the oxide film in the oxidation. Accordingly, the impurity concentration in the channel region of the P-type substrate region 3 can be easily controlled, so as to attain a desired threshold voltage Vt.

Also, in this embodiment, the P-type impurity used for forming the P-type substrate region 3 is ion implanted into the semiconductor substrate S through the polysilicon film 5A and the protection insulating film 11, and therefore, the semiconductor device having the trench MIS gate structure can be fabricated while preventing degradation of the film quality of the gate insulating film 4 otherwise caused in the ion implantation.

Furthermore, in this embodiment, since the abrupt impurity profile as shown in FIG. 1B can be formed in the P-type substrate region 3, namely, since the impurity profile of the channel region can be prevented from being broad, it is possible to suppress cancellation of the impurity concentration of the source/drain regions. In other words, the resistance of the device can be advantageously reduced. Also, the threshold voltage can be easily controlled by controlling the peak concentration of the impurity profile, and hence, the channel length can be advantageously shortened.

In this embodiment, the peak position of the concentration profile of the second conductivity type impurity shown in FIG. 1B is present in the P-type substrate region 3, which does not limit the invention. The peak position may be present in the high concentration N-type source region 8 or the low concentration N-type drain region 2.

### Embodiment 2

—Structure of Semiconductor Device—

A semiconductor device having a trench gate structure according to Embodiment 2 of the invention has the structure shown in FIG. 1A in the same manner as in Embodiment 1.

A difference of this embodiment from Embodiment 1 is a concentration profile of the second conductivity type impurity along the vertical direction of the semiconductor device of FIG. A.

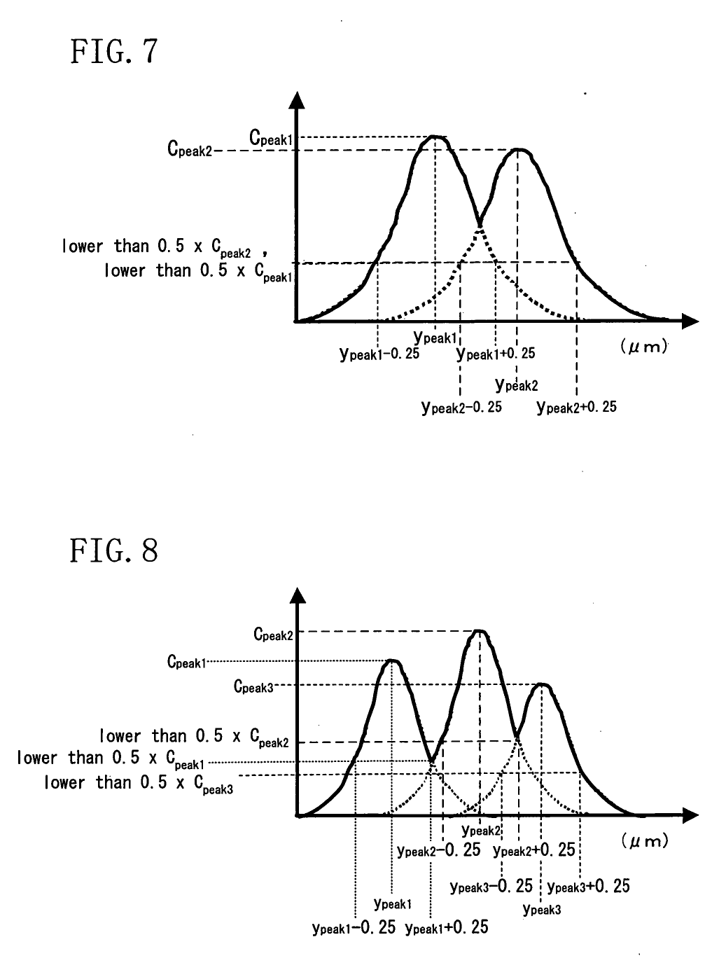

FIG. 7 shows a concentration profile along the depth direction of the impurity of the second conductivity type (the P-type) determining the threshold voltage Vt in the portion of the P-type substrate region 3 sandwiched between the adjacent trenches T.

As shown in FIG. 7, a profile having two peaks are formed by introducing the second conductivity type impurity into the semiconductor substrate S through two ion implantations in this embodiment, and thus, the threshold voltage Vt is determined.

In the case where two profiles corresponding to two peaks are complex in this manner, profiles defined by the respective two ion implantations are separated from each other by extending the profiles corresponding to the respective peaks (shown with a solid line) as shown with broken lines in FIG. 7.

As one characteristic of the semiconductor device of this embodiment, in each profile thus separated in the concentration profile of the second conductivity type impurity shown in FIG. 7, concentrations of the second conductivity type impurity in positions yₚₑₐₖ₁+0.25 and yₚₑₐₖ₁−0.25 respectively away upward and downward by 0.25 μm from a first peak position yₚₑₐₖ₁ are lower than a half of a first peak concentration Cₚₑₐₖ₁ and concentrations of the second conductivity type impurity in positions yₚₑₐₖ₂+0.25 and yₚₑₐₖ₂−0.25 respectively away upward and downward by 0.25 μm from a second peak position yₚₑₐₖ₂ are lower than a half of a second peak concentration Cₚₑₐₖ₂. It goes without saying that the concentrations of the second conductivity type impurity in the positions yₚₑₐₖ₁±0.25 may be different from the concentrations of the second conductivity type impurity in the positions yₚₑₐₖ₂±0.25.

—Fabrication Procedures —

A method for fabricating the semiconductor device according to Embodiment 2 is basically the same as that of Embodiment 1 shown in FIGS. 3A through 3F, 4A through 4F, 5A through 5F and 6A through 6D.

A difference of this embodiment from Embodiment 1 is detail of the ion implantation shown in FIGS. 4C and 4D. Specifically, in this embodiment, a photoresist mask 52 having an opening in a predetermined region including a source region and a high concentration P-type substrate region to be formed later is formed on the polysilicon film SA. Thereafter, in forming a P-type substrate region 3 with a junction depth of, for example, approximately 1 μm by introducing a P-type impurity into an upper portion of the low concentration N-type drain region 2 through the polysilicon film SA and the protection insulating film 11 by the ion implantation using the photoresist mask 52, the ion implantation of the P-type impurity is performed in two stages. At this point, the first ion implantation is performed at implantation energy of, for example, 600 through 700 keV and a dose of, for example, 6.0×10¹² ions/cm², and the second ion implantation is performed at implantation energy of, for example, 450 through 550 keV and a dose of, for example, 2.0×10¹² ions/cm².

The procedures to be performed thereafter are the same as those of Embodiment 1 shown in FIGS. 4E, 4F, 5A through 5F and 6A through 6D. Although not shown in FIGS. 6C and 6D, a barrier metal layer may be formed over the semiconductor substrate S before forming the Al layer to be used as the contact electrode 10.

Thereafter, although not shown in the drawings, an interlayer insulating film, a contact plug, an interconnect to be connected to the contact plug and the like are formed on the semiconductor substrate S by the known technique.

In the embodiment described so far, the channel region of the P-type substrate region 3 is formed as shown in FIGS. 4C and 4D after the sacrificial oxide film formation of FIGS. 3C and 3D and the gate oxide film formation of FIGS. 3E and 3F. Therefore, the P-type impurity can be prevented from being excessively drawn into the oxide film in the oxidation. Accordingly, the impurity concentration in the channel region of the P-type substrate region 3 can be easily controlled, so as to attain a desired threshold voltage Vt.

Also, in this embodiment, the P-type impurity used for forming the P-type substrate region 3 is ion implanted into the semiconductor substrate S through the polysilicon film 5A and the protection insulating film 11, and therefore, the semiconductor device having the trench MIS gate structure can be fabricated while preventing degradation of the film quality of the gate insulating film 4 otherwise caused in the ion implantation.

Furthermore, in this embodiment, since the abrupt impurity profile as shown in FIG. 7 can be formed in the P-type substrate region 3, namely, since the impurity profile of the channel region can be prevented from being broad, it is possible to suppress cancellation of the impurity concentration of the source/drain regions. In other words, the resistance of the device can be advantageously reduced. Also, the degree of freedom of the threshold voltage and the degree of freedom of channel length control can be improved by controlling the peak concentration of the impurity profile.

In this embodiment, each peak position of the concentration profile of the second conductivity type impurity shown in FIG. 7 is present in the P-type substrate region 3, which does not limit the invention. (One or all of) the peak positions may be present in the high concentration N-type source region 8 or the low concentration N-type drain region 2.

### Embodiment 3

—Structure of Semiconductor Device—

A semiconductor device having a trench gate structure according to Embodiment 3 of the invention has the structure shown in FIG. 1A in the same manner as in Embodiment 1.

A difference of this embodiment from Embodiment 1 is a concentration profile of the second conductivity type impurity along the vertical direction of the semiconductor device of FIG. 1A.

FIG. 8 shows a concentration profile along the depth direction of the impurity of the second conductivity type (the P-type) determining the threshold voltage Vt in the portion of the P-type substrate region 3 sandwiched between the adjacent trenches T.

As shown in FIG. 8, a profile having three peaks are formed by introducing the second conductivity type impurity into the semiconductor substrate S through three ion implantations in this embodiment, and thus, the threshold voltage Vt is determined.

In the case where a plurality of profiles corresponding to a plurality of peaks are complex in this manner, profiles defined by the respective ion implantations are separated from one another by extending the profiles corresponding to the respective peaks (shown with a solid line) as shown with broken lines in FIG. 8.

As one characteristic of the semiconductor device of this embodiment, in each profile thus separated in the concentration profile of the second conductivity type impurity shown in FIG. 8, concentrations of the second conductivity type impurity in positions yₚₑₐₖ₁+0.25 and yₚₑₐₖ₁−0.25 respectively away upward and downward by 0.25 μm from a first peak position yₚₑₐₖ₁ are lower than a half of a first peak concentration Cₚₑₐₖ₁, concentrations of the second conductivity type impurity in positions yₚₑₐₖ₂+0.25 and yₚₑₐₖ₂−0.25 respectively away upward and downward by 0.25 μm from a second peak position yₚₑₐₖ₂ are lower than a half of a second peak concentration Cₚₑₐₖ₂, and concentrations of the second conductivity type impurity in positions yₚₑₐₖ₃+0.25 and yₚₑₐₖ₃−0.25 respectively away upward and downward by 0.25 μm from a third peak position yₚₑₐₖ₃ are lower than a half of a third peak concentration Cₚₑₐₖ₃.

—Fabrication Procedures—

A method for fabricating the semiconductor device according to Embodiment 3 is basically the same as that of Embodiment 1 shown in FIGS. 3A through 3F, 4A through 4F, 5A through 5F and 6A through 6D.

A difference of this embodiment from Embodiment 1 is detail of the ion implantation shown in FIGS. 4C and 4D. Specifically, in this embodiment, a photoresist mask 52 having an opening in a predetermined region including a source region and a high concentration P-type substrate region to be formed later is formed on the polysilicon film 5A. Thereafter, in forming a P-type substrate region 3 with a junction depth of, for example, approximately 1 μm by introducing a P-type impurity into an upper portion of the low concentration N-type drain region 2 through the polysilicon film 5A and the protection insulating film 11 by the ion implantation using the photoresist mask 52, the ion implantation of the P-type impurity is performed in three stages. At this point, the first ion implantation is performed at implantation energy of, for example, 600 through 700 keV and a dose of, for example, 6.0×10¹² ions/cm², the second ion implantation is performed at implantation energy of, for example, 500 through 600 keV and a dose of, for example, 2.0×10¹² ions/cm², and the third ion implantation is performed at implantation energy of, for example, 400 keV and a dose of, for example, 5.0×10¹² ions/cm².

The procedures to be performed thereafter are the same as those of Embodiment 1 shown in FIGS. 4E, 4F, 5A through 5F and 6A through 6D. Although not shown in FIGS. 6C and 6D, a barrier metal layer may be formed over the semiconductor substrate S before forming the Al layer to be used as the contact electrode 10.

Thereafter, although not shown in the drawings, an interlayer insulating film, a contact plug, an interconnect to be connected to the contact plug and the like are formed on the semiconductor substrate S by the known technique.

In the embodiment described so far, the channel region of the P-type substrate region 3 is formed as shown in FIGS. 4C and 4D after the sacrificial oxide film formation of FIGS. 3C and 3D and the gate oxide film formation of FIGS. 3E and 3F. Therefore, the P-type impurity can be prevented from being excessively drawn into the oxide film in the oxidation. Accordingly, the impurity concentration in the channel region of the P-type substrate region 3 can be easily controlled, so as to attain a desired threshold voltage Vt.

Also, in this embodiment, the P-type impurity used for forming the P-type substrate region 3 is ion implanted into the semiconductor substrate S through the polysilicon film 5A and the protection insulating film 11, and therefore, the semiconductor device having the trench MIS gate structure can be fabricated while preventing degradation of the film quality of the gate insulating film 4 otherwise caused in the ion implantation.

Furthermore, in this embodiment, since the abrupt impurity profile as shown in FIG. 8 can be formed in the P-type substrate region 3, namely, since the impurity profile of the channel region can be prevented from being broad, it is possible to suppress cancellation of the impurity concentration of the source/drain regions. In other words, the resistance of the device can be advantageously reduced. Also, the degree of freedom of the threshold voltage and the degree of freedom of channel length control can be improved by controlling the peak concentration of the impurity profile. Furthermore, the resistance of the P-type substrate region 3 can be suppressed, so as to avoid a trouble caused by a parasitic transistor, such as degradation of a current-voltage characteristic designated as snap back caused when a parasitic bipolar transistor is conductive.

In this embodiment, each peak position of the concentration profile of the second conductivity type impurity shown in FIG. 8 is present in the P-type substrate region 3, which does not limit the invention. (One, two or all of) the peak positions may be present in the high concentration N-type source region 8 or the low concentration N-type drain region 2.

Although the P-type substrate region 3 is formed by introducing the second conductivity type impurity into the semiconductor substrate S through the three ion implantations in this embodiment, the ion implantation of the second conductivity type impurity may be performed in four or more stages.

In each of Embodiments 1 through 3, the semiconductor substrate S may be replaced with a single silicon substrate or an insulating substrate on which a semiconductor layer such as an epitaxial layer is formed.

Although a BPSG film is used as the buried insulating film 6 in each of Embodiments 1 through 3, another kind of insulating film may be used instead.

Furthermore, in each of Embodiments 1 through 3, after forming the polysilicon film 5A to be made into the gate electrode 5, the P-type substrate region 3 is formed and then the polysilicon film 5A is etched to form the gate electrode 5. Instead, after forming the gate insulating film 4, the P-type substrate region 3 may be formed before forming the polysilicon film 5A and forming the gate electrode 5. Alternatively, the P-type substrate region 3 may be formed after forming the gate electrode 5.

Although the N-channel MIS transistor is exemplified in each of Embodiments 1 through 3, the present invention is applicable to a P-channel MIS transistor, and similar effects can be attained also in this-case.

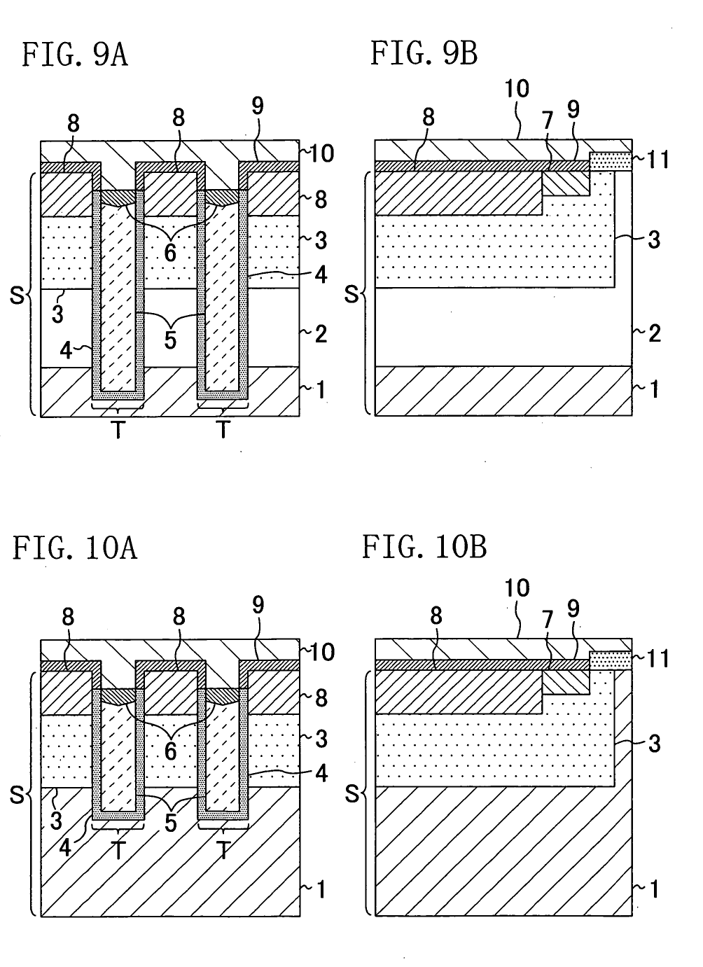

In each of Embodiments 1 through 3, the trench T is formed so as to penetrate the high concentration N-type source region 8 and the P-type substrate region 3 and reach the low concentration N-type drain region 2 in the semiconductor substrate S. Instead, for example, as shown in FIGS. 9A and 9B, the trench T may be formed to be sufficiently deep for penetrating the high concentration N-type source region 8, the P-type substrate region 3 and the low concentration N-type drain region 2 and reaching the high concentration N-type drain region 1 in the semiconductor substrate S. Also in this case, similar effects to those of Embodiments 1 through 3 can be attained. At this point, FIG. 9A is a cross-sectional view of this modification taken from the front side of FIG. 1A and FIG. 9B is a cross-sectional view of this modification taken from the right side of FIG. 1A.

Furthermore, in each of Embodiments 1 through 3, the drain region includes the high concentration N-type drain region 1 and the low concentration N-type drain region 2 provided on the high concentration N-type drain region 1. Instead, for example, as shown in FIGS. 10A and 10B, the low concentration N-type drain region 2 may be omitted. Specifically, the P-type substrate region 3 may be formed not on the low concentration N-type drain region 2 but directly on the high concentration N-type drain region 1, and the trench T may be formed so as to penetrate through the high concentration N-type source region 8 and the P-type substrate region 3 and to reach the high concentration N-type drain region 1. Also in this case, similar effects to those of Embodiments 1 through 3 can be attained. At this point, FIG. 10A is a cross-sectional view of this modification taken from the front side of FIG. 1A and FIG. 10B is a cross-sectional view of this modification taken from the right side of FIG. 1A.

What is claimed is:

1. A method for fabricating a semiconductor device comprising the steps of:
(a) forming a first semiconductor region of a first conductivity type in a semiconductor substrate;
(b) forming a trench reaching a given portion of said first semiconductor region in said semiconductor substrate;
(c) forming a gate insulating film on an inner wall of said trench;
(d) forming a second semiconductor region of a second conductivity type on said first semiconductor region in said semiconductor substrate after the step (c);
(e) forming a gate electrode of the first conductivity type on said gate insulating film within said trench; and
(f) forming a third semiconductor region of the first conductivity type on said second semiconductor region in said semiconductor substrate,
wherein said gate electrode is formed on said gate insulating film so as to extend over said second semiconductor region, a portion of said first semiconductor region disposed below said second semiconductor region and a portion of said third semiconductor region disposed on said second semiconductor region in the step (e).

2. The method for fabricating a semiconductor device of claim 1,
wherein said gate electrode is formed to have an upper face thereof positioned between an upper face and a lower face of said third semiconductor region in the step (e).

3. The method for fabricating a semiconductor device of claim 1, further comprising, after the step (e), a step (g) of forming an insulating film for covering an upper face of said gate electrode within said trench,
wherein said insulating film is formed to have an upper face thereof positioned between an upper face and a lower face of said third semiconductor region.

4. The method for fabricating a semiconductor device of claim 1, further comprising, after the step (e), a step (h) of forming a silicide layer on a portion of said third semiconductor region exposed within said trench.

5. The method for fabricating a semiconductor device of claim 1,
wherein said second semiconductor region is formed by implanting an impurity of the second conductivity type into said semiconductor substrate through a plurality of ion implantations different in implantation energy.

6. The method for fabricating a semiconductor device of claim 1, further comprising, between the step (b) and the step (c), a step of forming an oxide film by sacrificially oxidizing the inner wall of said trench and removing said oxide film.

7. The method for fabricating a semiconductor device of claim 1,
wherein the step (d) is executed after the step (e).

8. The method for fabricating a semiconductor device of claim 1,
wherein the step (e) includes a sub-step (e1) of filling a conducting film in said trench and a sub-step (e2) of forming said gate electrode by etching said conducting film,
the step (d) is executed between the sub-step (e1) and the sub-step (e2), and
said second semiconductor region is formed by introducing an impurity of the second conductivity type into said semiconductor substrate through said conducting film by ion implantation.

9. A semiconductor device comprising:
a first semiconductor region of a first conductivity type formed in a semiconductor substrate;
a second semiconductor region of a second conductivity type formed on said first semiconductor region in said semiconductor substrate;
a third semiconductor region of the first conductivity type formed on said second semiconductor region in said semiconductor substrate;
a trench penetrating said third semiconductor region and said second semiconductor region and reaching said first semiconductor region;
a gate insulating film formed on an inner wall of said trench; and
a gate electrode of the first conductivity type formed on said gate insulating film within said trench,
wherein said gate electrode is formed on said gate insulating film so as to extend over said second semiconductor region, a portion of said first semiconductor region disposed below said second semiconductor region and a portion of said third semiconductor region disposed on said second semiconductor region and includes an impurity of the second conductivity type.

10. The semiconductor device of claim 9,
wherein in a concentration distribution of the impurity of the second conductivity type in a portion of said second semiconductor region disposed between said first semiconductor region and said third semiconductor region on a side of said trench, concentrations in positions away respectively upward and downward from a peak position by 0.25 μm are lower than a half of a peak concentration.

11. The semiconductor device of claim 9,
wherein said gate electrode has an upper face positioned between an upper face and a lower face of said third semiconductor region.

12. The semiconductor device of claim 9, further comprising an insulating film covering an upper face of said gate electrode within said trench,
wherein said insulating film has an upper face positioned between an upper face and a lower face of said third semiconductor region.

13. The semiconductor device of claim 12, further comprising a silicide layer formed on a portion of said third semiconductor region disposed above said insulating film within said trench.

14. The semiconductor device of claim 9,
wherein a concentration distribution of the impurity of the second conductivity type in said second semiconductor region has two peaks.

15. The semiconductor device of claim 9,
wherein a concentration distribution of the impurity of the second conductivity type in said second semiconductor region has three or more peaks.

16. The semiconductor device of claim 9,
wherein said first semiconductor region includes a fourth semiconductor region including an impurity of the first conductivity type in a relatively high concentration and a fifth semiconductor region provided on said fourth semiconductor region and including the impurity of the first conductivity type in a relatively low concentration.

17. The semiconductor device of claim 9,
wherein the impurity of the second conductivity type included in said gate electrode is introduced into said gate electrode through ion implantation performed for forming said second semiconductor region.
